(19) United States
(12) Patent Application Publication
(10) Pub. No.: US 2025/0093393 A1
(43) Pub. Date: Mar. 20, 2025

(54) POWER CONSUMPTION ESTIMATING DEVICE, POWER CONSUMPTION ESTIMATION SYSTEM, AND POWER CONSUMPTION ESTIMATION METHOD

(71) Applicant: Hitachi, Ltd., Tokyo (JP)

(72) Inventors: Pritam Jaywant CHAUDHARI, Tokyo (JP); Satoshi KANEKO, Tokyo (JP); Yoji OZAWA, Tokyo (JP)

(21) Appl. No.: 18/727,650

(22) PCT Filed: Feb. 8, 2023
(86) PCT No.: PCT/JP2023/004076

§ 371 Date: Jul. 10, 2024

(30) Foreign Application Priority Data
Mar. 2, 2022 (JP) 2022-031431

(51) Int. Cl. G01R 21/133

(52) U.S. Cl. CPC G01R 21/133

(57) ABSTRACT

Provided is power consumption estimation means that can accurately estimate the power consumption of diverse applications. A power consumption estimating device includes a metadata DB that stores past application metadata related to each of past applications, a power consumption DB including power consumption information representing the power consumption of the past applications, and a power consumption estimating section that estimates the power consumption of an estimation target application. The power consumption estimating section extracts target application metadata from an application manifest related to the estimation target application, calculates the degree of similarity of the target application metadata to the past application metadata, extracts, from the power consumption DB, first power consumption information corresponding to a similar application having a degree of similarity which satisfies a predetermined degree-of-similarity criterion, and outputs the first power consumption information as a first power consumption estimation result.

### TECHNICAL FIELD

The present invention relates to a power consumption estimating device, a power consumption estimation system, and a power consumption estimation method.

### BACKGROUND ART

In a distributed computing environment including many servers (hereinafter, called “nodes”) that are connected with each other, it is important to efficiently select an optimal node for executing a workload of a particular application. Various criteria such as the numbers of processors of nodes, the memory and storage capacity of the nodes, or the power consumption efficiency of the nodes are used for selection of an optimal node for executing a particular workload.

In particular, in recent years, the power consumption of workloads is an important matter to be examined for deployment of applications along with the introduction of green IT or the like for which careful consideration for the influence of information communication technologies on the global environment is demanded, and workload deployment conscious of power consumption for purposes such as reduction of power consumption, enhancement of the usage of renewable energy, and the like has been demanded.

For realization of workload deployment conscious of power consumption, means for estimating the power consumption of a workload of an application is used before a node to be the deployment destination of the application is determined.

For example, as one of means for estimating the power consumption of a workload, Patent Document 1 discloses “a method for operating a data processing system including a plurality of nodes, comprising: receiving an indication of a mode for a first job; determining available power for the first job based on the mode; adjusting a first frequency of the plurality of nodes that run the first job, based on the available power, the first frequency being common to the plurality of nodes running the first job; allocating first power for the first job that runs on the plurality of nodes based on the first frequency; determining whether or not the first frequency is greater than a predetermined frequency; and determining available power for a second job when the first frequency is greater than the predetermined frequency.”

In addition, Patent Document 2 discloses a technology by which “devices and techniques for estimating power consumption and efficiency of application containers configured to run on a server system, such as a cloud server, are provided. In an example, the method includes creating a benchmark application container, naming the benchmark application container on a host server, collecting power consumption information of the host server, collecting resource usage information of the benchmark application container using an artificial workload, building a statistical model by using the power consumption information and the resource usage information, and generating a first power model of the host server.”

### PRIOR ART DOCUMENT

### Patent Documents

Patent Document 1: U.S. Pat. No. 9,575,536
Patent Document 2: U.S. Pat. No. 10, 432, 491

### SUMMARY OF THE INVENTION

### Problems to be Solved by the Invention

Patent Document 1 described above discloses means for estimating the power consumption of a workload of a particular application by referring to information about the maximum power or average power obtained in a case where a workload of an application of the same type is executed on a particular node.

In addition, Patent Document 2 discloses means for creating a power model for estimating power consumption, by causing a benchmark application to run on a predetermined node, measuring information about the resource usage such as the processor usage, memory usage, or I/O usage for a workload of the benchmark application, and processing the measured information about the resource usage by using regression modeling.

However, in practice, each node in a distributed computing environment is demanded to host various applications for business analysis, media streaming, web services, and the like, and the power consumption of workloads varies depending on applications. Since the power consumption of workloads varies depending on applications in this manner, the power consumption of various applications that each node can host cannot be estimated accurately with only a single power model for the node, and it is necessary to build a power model for each application. However, there are diverse applications, and it is not realistic to build in advance power models for all the applications that a node can host.

However, none of Patent Document 1 and Patent Document 2 take into consideration the influence of the diversity of applications mentioned above on power consumption estimation. More specifically, although, in Patent Document 1 and Patent Document 2, a benchmark application having characteristics similar to the characteristics of a target application is used for estimation of the power consumption of a workload of the target application, it is not always the case that a benchmark application similar to a target application is available.

Although Patent Document 1 proposes power estimation based on only the maximum power consumption value of a node in a case where there are no benchmark applications similar to a target application, the maximum power consumption is not enough to obtain an accurate power consumption estimate of a particular application. In addition, although Patent Document 2 proposes means for adjusting coefficients of a power model that has already been built, in a case where there are no benchmark applications similar to a target application, correction of the power model can become a significant burden if the diversity of applications is taken into consideration.

Therefore, the present disclosure has been made in view of the problems described above, and an object thereof is to provide power consumption estimation means that can accurately estimate the power consumption of diverse applications by calculating the degree of similarity between a target application to be deployed on a node in a distributed computing environment and each of applications executed in the past on the node, on the basis of metadata of the respective applications, and using information about power consumption measured about a past application satisfying a predetermined degree-of-similarity criterion.

### Means for Solving the Problems

In order to solve the problems described above, one of representative power consumption estimating devices of the present invention is a power consumption estimating device that estimates power consumption of an estimation target application to be deployed on a node cluster including a plurality of nodes, the power consumption estimating device including a metadata database that stores past application metadata related to each of past applications executed in a past on the node cluster, a power consumption database including power consumption information representing power consumption of the past applications, and a power consumption estimating section that estimates the power consumption of the estimation target application. The power consumption estimating section acquires an application manifest including information about the estimation target application, extracts, from the application manifest, target application metadata which is metadata related to the estimation target application, calculates a degree of similarity of the target application metadata to the past application metadata stored on the metadata database, in a case where there is a similar application having a calculated degree of similarity which satisfies a predetermined degree-of-similarity criterion in the past applications, extracts, from the power consumption database, first power consumption information corresponding to the similar application, and outputs the first power consumption information as a first power consumption estimation result representing a power consumption estimate of the estimation target application.

### Advantages of the Invention

The present disclosure can provide power consumption estimation means that can accurately estimate the power consumption of diverse applications by calculating the degree of similarity between a target application to be deployed on a node in a distributed computing environment and each of applications executed in the past on the node, on the basis of metadata of the respective applications, and using information about power consumption measured about a past application satisfying a predetermined degree-of-similarity criterion.

Problems, configurations, and advantages other than those described above are made clear by explanation in the following Modes for Carrying Out the Invention.

### BRIEF DESCRIPTION OF THE DRAWINGS

FIG. 1 is a figure depicting a computer system for implementing an embodiment of the present disclosure.

FIG. 2 is a figure depicting an example of a configuration of a power consumption estimation system according to the embodiment of the present disclosure.

FIG. 3 is a flowchart depicting an example of a procedure of a power consumption estimation method according to the embodiment of the present disclosure.

FIG. 4 is a figure depicting a configuration example of a past application metadata database according to the embodiment of the present disclosure.

FIG. 5 is a figure depicting a configuration example of a past application power consumption database according to the embodiment of the present disclosure.

FIG. 6 is a figure depicting a configuration example of a past application profile according to the embodiment of the present disclosure.

FIG. 7 is a figure depicting an example of metadata conversion according to the embodiment of the present disclosure.

FIG. 8 is a figure depicting a configuration example of a text metadata conversion table according to the embodiment of the present disclosure.

FIG. 9 is a figure depicting a configuration example of an unstructured text metadata conversion table according to the embodiment of the present disclosure.

### MODES FOR CARRYING OUT THE INVENTION

Hereinbelow, an embodiment of the present invention is explained with reference to the figures. Note that the embodiment does not limit the present invention. In addition, in illustrations in the figures, identical portions are denoted with identical reference symbols.

### Overview of Present Disclosure

First, before an embodiment of the present disclosure is explained, an overview of the present disclosure is explained.

As mentioned above, since there are diverse applications, and the power consumption of workloads varies depending on applications, there is a problem that it is difficult to accurately estimate the power consumption of a node cluster that is demanded to host and execute diverse applications.

In view of this, the present disclosure makes it possible to accurately estimate the power consumption of diverse applications by calculating the degree of similarity between a target application (hereinafter, called an “estimation target application”) to be deployed on a node cluster in a distributed computing environment and each of applications executed in the past on the node (hereinafter, called “past applications”), on the basis of metadata of the respective applications, and using information about power consumption measured about a past application satisfying a predetermined degree-of-similarity criterion.

On the basis of the power consumption estimate of the application thus generated, the application can be deployed on an appropriate node cluster. In addition, by measuring and analyzing the actual power consumption of the application after the application is deployed on the appropriate node cluster, the precision of a power model for estimating power consumption taking into consideration the resource usage of the application can be evaluated. In a case where, as a result of the evaluation, the precision of the power model does not satisfy a predetermined criterion (i.e., in a case where an estimate generated by the power model differs from an actually measured value), the power model is updated on the basis of information about the actual power consumption of the application, so that the precision of the power model can be enhanced.

Meanwhile, in a case where there are no past applications having a calculated degree of similarity to the estimation target application which degree satisfies the predetermined degree-of-similarity criterion, a power consumption estimate of the estimation target application is generated on the basis of the average power consumption value of the past applications executed on the node cluster. Thereafter, the estimation target application is deployed on an appropriate node cluster on the basis of the power consumption estimate. In addition, by measuring and analyzing the actual power consumption of the deployed application, a new power model corresponding to the application can be built.

By causing node clusters to host various applications, and updating an existing power model of each hosted application, creating a new power model, and so on over time in this manner, a repertoire of power models corresponding to diverse applications is built, and accordingly, it becomes possible to accurately estimate the power consumption of the diverse applications.

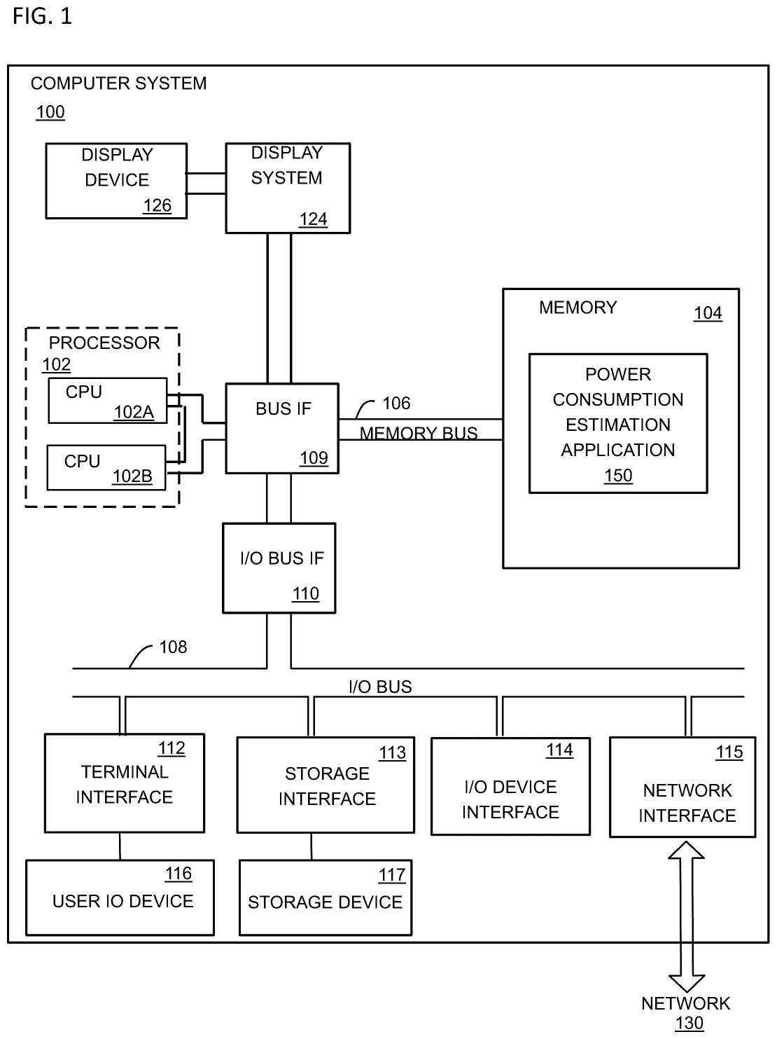

Next, a computer system 100 for implementing an implementation example of the present disclosure is explained with reference to FIG. 1. Mechanisms and devices of various implementation examples disclosed in the present specification may be applied to any appropriate computing system. Main components of the computer system 100 include one or more processors 102, a memory 104, a terminal interface 112, a storage interface 113, an I/O (input/output) device interface 114, and a network interface 115. These components may be interconnected via a memory bus 106, an I/O bus 108, a bus interface unit 109, and an I/O bus interface unit 110.

The computer system 100 may include one or more general-purpose programmable central processing units (CPUs) 102A and 102B that are collectively referred to as the processors 102. In an implementation example, the computer system 100 may include a plurality of processors, and, in another implementation example, the computer system 100 may be a system with a single CPU. Each processor 102 may execute commands stored on the memory 104 and include an on-board cache.

In an implementation example, the memory 104 may include a (volatile or non-volatile) random access semiconductor memory, storage device, or storage medium for storing data and programs. The memory 104 may store all or part of programs, modules, and data structures that are used to implement functions explained in the present specification. For example, the memory 104 may have stored thereon a power consumption estimation application 150. In an implementation example, the power consumption estimation application 150 may include commands or descriptions for executing functions mentioned later on the processors 102.

In an implementation example, the power consumption estimation application 150 may be implemented on hardware via a semiconductor device, a chip, a logic gate, a circuit, a circuit card, and/or another physical hardware device, instead of a processor-based system, or in addition to a processor-based system. In an implementation example, the power consumption estimation application 150 may include data other than commands or descriptions. In an implementation example, a camera, a sensor, or another data input device (not depicted) may be provided such that it directly communicates with the bus interface unit 109, the processors 102, or other hardware of the computer system 100.

The computer system 100 may include the bus interface unit 109 that performs communication between the processors 102, the memory 104, a display system 124, and the I/O bus interface unit 110. The I/O bus interface unit 110 may be coupled with the I/O bus 108 for transferring data between the I/O bus interface unit 110 and the various I/O units. The I/O bus interface unit 110 may communicate with the plurality of I/O interface units 112, 113, 114, and 115, known also as an I/O processor (IOP) or an I/O adaptor (IOA), via the I/O bus 108.

The display system 124 may include a display controller and/or a display memory. The display controller can provide video data and/or audio data to a display device 126. In addition, the computer system 100 may include one or more devices such as sensors configured to collect data and provide the data to the processors 102.

For example, the computer system 100 may include: a biometric sensor that collects heart rate data, stress level data, and the like; an environment sensor that collects humidity data, temperature data, pressure data, and the like; a motion sensor that collects acceleration data, movement data, and the like; and the like. Sensors of types other than these can also be used. The display system 124 may be connected to the display device 126 such as a single display screen, a television, a tablet, or a portable device.

The I/O interface units have a function to communicate with various storages or I/O devices. For example, a user I/O device 116 like a user output device such as a video display device or a speaker television, or a user input device such as a keyboard, a mouse, a keypad, a touch pad, a track ball, a button, a write pen, or another pointing device can be attached to the terminal interface unit 112. By operating the user input device by using a user interface, a user may input input data or instructions to the user I/O device 116 and the computer system 100 and receive output data from the computer system 100. For example, the user interface may be displayed on the display device, reproduced by a speaker, printed via a printer, and so on, via the user I/O device 116.

One or more disk drives or a direct access storage device 117 (which is typically a magnetic disk drive storage device, but may be a disk drive array configured to appear to be a single disk drive, or another storage device) can be attached to the storage interface 113. In an implementation example, the storage device 117 may be implemented as any secondary storage device. Contents of the memory 104 may be stored on the storage device 117 and read out from the storage device 117 as necessary. The I/O device interface 114 may provide an interface for another I/O device such as a printer or a facsimile machine. The network interface 115 may provide such a communication path that the computer system 100 and another device can intercommunicate. For example, this communication path may be a network 130.

In an implementation example, the computer system 100 may be a device, such as a multi user main frame computer system, a single user system, or a server computer, that does not have a direct user interface but receives requests from another computer system (client). In another implementation example, the computer system 100 may be a desktop computer, a portable computer, a laptop personal computer, a tablet computer, a pocket computer, a telephone, a smartphone, or any other appropriate electronic equipment.

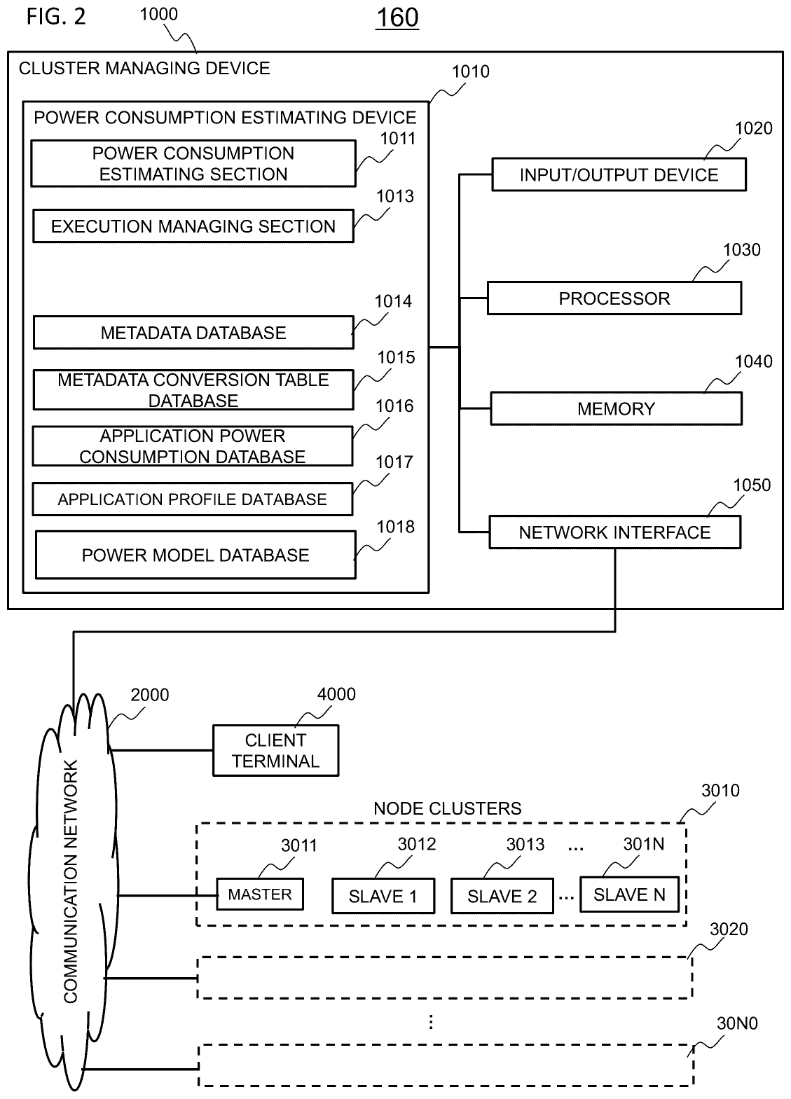

Next, a configuration of a power consumption estimation system according to the embodiment of the present disclosure is explained with reference to FIG. 2.

FIG. 2 is a figure depicting an example of a configuration of a power consumption estimation system 160 according to the embodiment of the present disclosure. As depicted in FIG. 2, the power consumption estimation system 160 according to the embodiment of the present disclosure mainly includes a cluster managing device 1000, a communication network 2000, node clusters 3010, 3020, . . . , and 30N0, and a client terminal 4000. As depicted in FIG. 2, in the power consumption estimation system 160, the cluster managing device 1000, the node clusters 3010, 3020, . . . , and 30N0, and the client terminal 4000 are connected communicatively with each other via the communication network 2000.

For example, the communication network 2000 may include a local area network (LAN), a wide area network (WAN), a satellite network, a cable network, a Wi-Fi network, or any combination of these.

The client terminal 4000 is a terminal device used by a requester who requests the cluster managing device 1000 to execute or manage predetermined applications. For example, the applications here may include business analysis applications, media streaming applications, web service applications, and the like and are not limited to any particular ones here. The client terminal 4000 communicates with the cluster managing device 1000 via the communication network 2000. The client terminal 4000 may transmit an execution request including an application manifest having information about a requested application, to the cluster managing device 1000 via the communication network 2000.

The node clusters 3010, 3020, . . . , and 30N0 are groups of nodes included in what is generally called a distributed computing environment, and are configured to execute applications deployed by the cluster managing device 1000 mentioned later. It is assumed here that respective nodes in the node clusters 3010, 3020, . . . , and 30N0 are nodes of the same type (i.e., nodes having identical server configuration).

As depicted in FIG. 2, the node cluster 3010 includes one master node 3011 and a plurality of slave nodes 3012, 3013, and 301N. The master node 3011 communicates with the cluster managing device 1000 via the communication network 2000.

The master node 3011 is a node for managing execution of applications on the slave nodes 3012, 3013, and 301N. The master node 3011 assigns, to an appropriate slave node, a workload of a predetermined application in accordance with an instruction from the cluster managing device 1000 mentioned later, and then causes the appropriate slave node to execute the workload. In addition, the master node 3011 measures the power consumption of each of the slave nodes 3012, 3013, and 301N and the resource usage (processor usage, memory usage, I/O usage, etc.) of workloads of applications being executed on the slave nodes 3012, 3013, and 301N, and transmits information about the power consumption and the resource usage to the cluster managing device 1000.

The cluster managing device 1000 is a server device for deploying an application requested by an execution request received from the client terminal 4000 on any of the node clusters 3010, 3020, and 30N0. As depicted in FIG. 2, the cluster managing device 1000 includes a power consumption estimating device 1010, an input/output device 1020, a processor 1030, a memory 1040, and a network interface 1050.

For example, the cluster managing device 1000 may be configured using the computer system 100 depicted in FIG. 1.

The network interface 1050 is a functional section that establishes communication between the cluster managing device 1000 and external sections (the node clusters 3010, 3020, . . . , and 30N0 and the client terminal 4000) via the communication network 2000.

The input/output device 1020 is a functional section that provides an interface for inputting information to the cluster managing device 1000, checking information output from the cluster managing device 1000, and so on.

The processor 1030 executes program commands (e.g., functions of each functional section in the power consumption estimating device 1010) acquired by the memory 1040 mentioned later.

The memory 1040 acquires program commands that are stored on the power consumption estimating device 1010 mentioned later and that are for realizing functions of functional sections, and provides the program commands to the processor 1030.

The power consumption estimating device 1010 is a device for implementing power consumption estimation means according to the embodiment of the present disclosure. As depicted in FIG. 2, the power consumption estimating device 1010 includes a power consumption estimating section 1011, an execution managing section 1013, a metadata database 1014, a metadata conversion table database 1015, an application power consumption database 1016, an application profile database 1017, and a power model database 1018.

Whereas, for example, each functional section (the power consumption estimating section 1011 or the execution managing section 1013) of the power consumption estimating device 1010 may be configured as a software module in the power consumption estimation application 150 depicted in FIG. 1 or may be configured as a dedicated hardware device, for convenience of explanation, each functional section is configured as a software module in the case explained as an example in the present disclosure.

The power consumption estimating section 1011 is a functional section for generating a power consumption estimation result (first power consumption estimation result) which is an estimate of the power consumed for a workload of a target application (hereinafter, called an “estimation target application”) to be deployed on the node clusters 3010, 3020, . . . and 30N0. Here, a “workload of an application” means a processing task executed in realizing a function of a certain application. A workload of an application may be divided and assigned individually to different nodes in a node cluster.

Note that details of functions of the power consumption estimating section 1011 are mentioned later, and accordingly, explanations thereof are omitted here.

For example, the execution managing section 1013 is a functional section for deploying an estimation target application on an appropriate node cluster 3010, 3020, . . . , or 30N0 on the basis of the power consumption estimation result (first power consumption estimation result) of the estimation target application which result is generated by the power consumption estimating section 1011.

The metadata database 1014 is a database that stores metadata related to applications executed by the node clusters 3010, 3020, . . . and 30N0 (e.g., applications deployed on the node clusters in the past).

The metadata conversion table database 1015 is a table for converting metadata of applications executed by the node clusters 3010, 3020, . . . , and 30N0 from text formats into vector formats.

The application power consumption database 1016 is a database that stores power consumption information about applications executed by the node clusters 3010, 3020, . . . , and 30N0, information about the storage locations of application profiles representing the resource usage of the applications, and information about the storage locations of power models for estimating power consumption taking into consideration the resource usage of the applications.

The application profile database 1017 is a database that stores information about application profiles representing the resource usage of applications.

The power model database 1018 is a database that stores power models for estimating power consumption taking into consideration the resource usage of applications executed by the node clusters 3010, 3020, . . . , and 30N0 (i.e., for generating second power consumption estimation results). For example, the power models here may be Python objects that are stored in a pickle file and that designate trained model coefficients.

While the first power consumption estimation result that is generated by the power consumption estimating section 1011 mentioned above and that is used for determining a node to be the deployment destination of the estimation target application includes information such as the average power consumption value or maximum power consumption value of a similar application, the second power consumption estimation results generated on the basis of power models stored in the power model database 1018 are predictions of power consumption taking into consideration the usage of resources to be used by the estimation target application, and accordingly, can represent estimates finer than the first power consumption estimation result.

The power consumption estimation system 160 explained above can provide power consumption estimation means that can accurately estimate the power consumption of diverse applications.

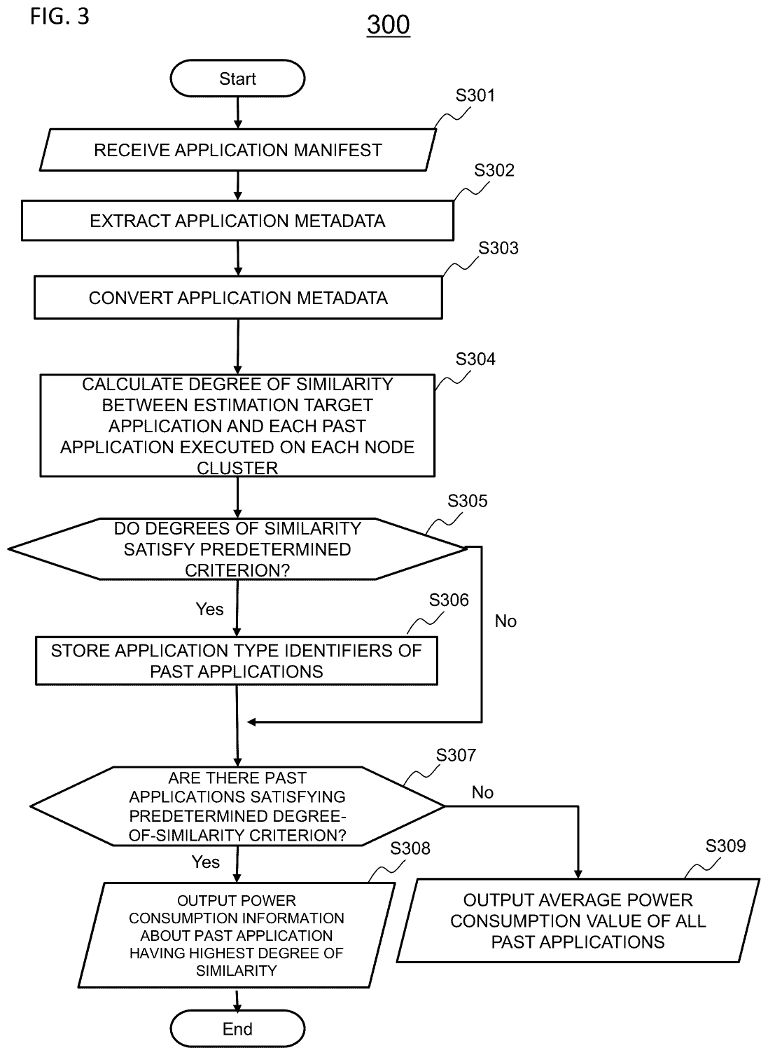

Next, an example of a procedure of a power consumption estimation method according to the embodiment of the present disclosure is explained with reference to FIG. 3.

FIG. 3 is a flowchart depicting an example of a procedure of a power consumption estimation method 300 according to the embodiment of the present disclosure. The power consumption estimation method 300 depicted in FIG. 3 is a method for accurately estimating the power consumption of diverse applications by calculating the degree of similarity between a target application (hereinafter, called an “estimation target application”) to be deployed on a node cluster in a distributed computing environment and each of applications executed in the past on the node (hereinafter, called “past applications”), on the basis of metadata of the respective applications, and using information about power consumption measured about a past application satisfying a predetermined degree-of-similarity criterion. For example, the power consumption estimation method 300 is implemented by the power consumption estimating section 1011 in the power consumption estimating device 1010 mentioned above.

First, at Step S301, for example, the power consumption estimating section 1011 receives an application manifest of the estimation target application from the client terminal 4000 via the communication network 2000 mentioned above. For example, the application manifest may be included in an execution request for deployment of the estimation target application on any of the node clusters 3010, 3020, . . . , and 30N0.

The application manifest is a description of components included in the target application to be deployed on the node clusters 3010, 3020, . . . , and 30N0, and, for example, may include a description of a service provided to the application (also referred to as a microservice), a description of containers included in the service, a description of a job (processing task) included in the application, and the like. These descriptions of the service, the containers, and the job, and the like are collectively referred to as “application resources.”

Next, at Step S302, the power consumption estimating section 1011 extracts application metadata related to the estimation target application (hereinafter, called “target application metadata”) from the application manifest received at Step S301. The target application metadata related to the estimation target application is information designating specifications of the respective application resources mentioned above. For example, the target application metadata may include the type of the service, the number of containers of the service, images for implementing the containers, a network protocol used for the service, processor and memory requirements of the containers, the position in the order of execution priority of the job, the position in the order of node priority for executing the containers, a label associated with the service, labels associated with the containers, a label associated with the job, and the like. In order to extract the target application metadata, the power consumption estimating section 1011 may use an existing information extraction technique, and there are no limitations in this regard here.

Next, at Step S303, the power consumption estimating section 1011 converts the target application metadata related to the estimation target application extracted at Step S302 into vector formats. Here, the power consumption estimating section 1011 may convert the target application metadata into vector formats by performing what is generally called one-hot encoding on the basis of the metadata conversion table mentioned above.

Note that details of a process of converting the target application metadata related to the estimation target application into vector formats are mentioned later, and accordingly, an explanation thereof is omitted here.

Next, at Step S304, the power consumption estimating section 1011 calculates, on the basis of respective pieces of application metadata, the degree of similarity between the estimation target application and each past application executed on each of the node clusters 3010, 3020, . . . , and 30N0. Here, the past applications mean applications that have been executed on any of the node clusters 3010, 3020, and 30N0 in the past.

More specifically, the power consumption estimating section 1011 acquires, from the metadata database 1014 mentioned above, past application metadata which is metadata of each past application executed on each of the node clusters 3010, 3020, and 30N0.

Thereafter, the power consumption estimating section 1011 calculates the degree of similarity of the target application metadata of the estimation target application extracted at Step S302 and converted into the vector formats at Step S303 to the past application metadata of each past application acquired from the metadata database 1014. As a scale of the degrees of similarity here, for example, the distances between the target application metadata and the past application metadata may be used. In this case, it can be said that the shorter the distance between the target application metadata and the past application metadata is, the higher the degree of similarity between the target application metadata and the past application metadata is.

It is assumed, as an example, that the target application metadata of the estimation target application is expressed by a metadata vector X including elements A, B, and C (a processor requirement, a memory requirement, the number of containers, etc.). Similarly, it is assumed that the past application metadata of a past application is expressed by a metadata vector x including elements a, b, and c (a processor requirement, a memory requirement, the number of containers, etc.).

In this case, a numerical metadata distance Dₙ between the target application metadata X and the past application metadata x may be calculated as the Minkowski distance, the Euclidean distance, or the like. A formula for calculating the distance Dₙ between the target application metadata X and the past application metadata x as the Euclidean distance is represented by Math. 1.

$${D}_{n} = \sqrt{{( A - a )}^{2} + {( B - b )}^{2} + {( C - c )}^{2} + …} \qquad [ Math . 1 ]$$

Whereas the entire application metadata is expressed by numerical values in the case explained above, application metadata may include metadata expressed by text such as container image names or service type labels. In this case, it is possible to convert the metadata in text formats into vector formats by performing a one-hot encoding technique using the metadata conversion table database 1015 mentioned later. It is assumed here that target application metadata converted into vector formats by the one-hot encoding technique is expressed by U and V, and past application metadata converted into vector formats by the one-hot encoding technique is expressed by u and v.

In this case, a text metadata distance Dₜ between the target application metadata U and V converted into the vector formats by the one-hot encoding technique and the past application metadata u and v converted into the vector formats by the one-hot encoding technique is determined by the following Math. 2.

$${D}_{t} = \sqrt{{‖ U . u ‖}^{2} + {‖ V . v ‖}^{2} + …} \qquad [ Math . 2 ]$$

Here, [[U.u]] means the magnitude of the inner product of U. and u.

A total distance DA including both the numerical metadata distance Dₙ and the text metadata distance Dₜ mentioned above is determined by the following Math. 3.

$${D}_{A} = \sqrt{{( A - a )}^{2} + {( B - b )}^{2} + {( C - c )}^{2} + … + {‖ U . u ‖}^{2} + {‖ V . v ‖}^{2} + …} \qquad [ Math . 3 ]$$

In addition, as another method for calculating the distances between pieces of application metadata, it is possible to weight application metadata (e.g., a particular metadata vector) and adjust the influence of particular application metadata on a total distance (i.e., emphasize a weight). As an example, application metadata in which a container image used by a particular application reads “Web Server B” more accurately identifies the application than application metadata in which an application service of a particular application reads “backend” does, and accordingly, the influence of the metadata with a higher identification capability on the total distance can be emphasized by setting a greater weight for a metadata vector of the application metadata in which the container image used by the particular application reads “Web Server B.”

Next, at Step S305, the power consumption estimating section 1011 determines whether or not the degree of similarity of the estimation target application to each past application calculated at Step S304 satisfies a predetermined degree-of-similarity criterion. For example, the predetermined degree-of-similarity criterion here may be set by an administrator of the power consumption estimation system 160 or may be set using an existing statistical technique. As an example, in a case where the scale of the degrees of similarity is the Euclidean distance mentioned above, the predetermined degree-of-similarity criterion here may designate an upper limit distance. Accordingly, values falling below the upper limit distance are determined as satisfying the degree-of-similarity criterion, and values exceeding the upper limit distance are determined as not satisfying the degree-of-similarity criterion.

In a case where any of the degrees of similarity calculated at Step S304 satisfies the predetermined degree-of-similarity criterion, the present process proceeds to Step S306, and, in a case where none of the degrees of similarity calculated at Step S304 satisfy the predetermined degree-of-similarity criterion, the present process proceeds to Step S307.

Next, at Step S306, the power consumption estimating section 1011 stores, in a predetermined memory area, an application type identifier that uniquely identifies the type of the past application satisfying the predetermined degree-of-similarity criterion. In a case where there are a plurality of past applications satisfying the predetermined degree-of-similarity criterion, the power consumption estimating section 1011 stores the application type identifiers and calculated degrees of similarity of the respective past applications. Hereinbelow, past applications having degrees of similarity to the estimation target application which degrees satisfy the degree-of-similarity criterion are called “similar applications.”

Next, at Step S307, after the calculation of the degrees of similarity between the estimation target application and all the past applications has been completed, the power consumption estimating section 1011 determines whether or not there are one or more past applications satisfying the predetermined degree-of-similarity criterion (i.e., similar applications of the estimation target application). In a case where it is determined that there are similar applications, the present process proceeds to Step S308, and, in a case where it is determined that there are no similar applications, the present process proceeds to Step S309.

In a case where there are similar applications, at Step S308, the power consumption estimating section 1011 selects a similar application having the highest degree of similarity from the similar applications whose application type identifiers and degrees of similarity have been stored at Step S306. Thereafter, the power consumption estimating section 1011 refers to the application power consumption database 1016 mentioned above, acquires, from the application power consumption database 1016 mentioned above, power consumption information about the selected similar application, and outputs, to the execution managing section 1013, the acquired power consumption information about the similar application as the first power consumption estimation result of the estimation target application. For example, the first power consumption estimation result here may include information such as an estimate of the average power consumption value of the estimation target application or the maximum power consumption value of the estimation target application.

In a case where there are no similar applications, at Step S309, the power consumption estimating section 1011 calculates the average power consumption value of all the past applications stored in the application power consumption database 1016, and outputs the calculated average power consumption value to the execution managing section 1013 as the first power consumption estimation result.

By using the power consumption information about the past application having the degree of similarity to the estimation target application which degree satisfies the predetermined degree-of-similarity criterion in this manner, the first power consumption estimation result that accurately estimates the power consumption of the estimation target application can be generated. In addition, thereafter, on the basis of the first power consumption estimation result, the execution managing section 1013 mentioned above can determine a node cluster to be an appropriate deployment destination of the estimation target application from the node clusters 3010, 3020, . . . , and 30N0. After determining the deployment destination, the execution managing section 1013 transmits a deployment instruction requesting the deployment of the estimation target application, to the master node of the determined node cluster, and deploys the estimation target application on the node cluster.

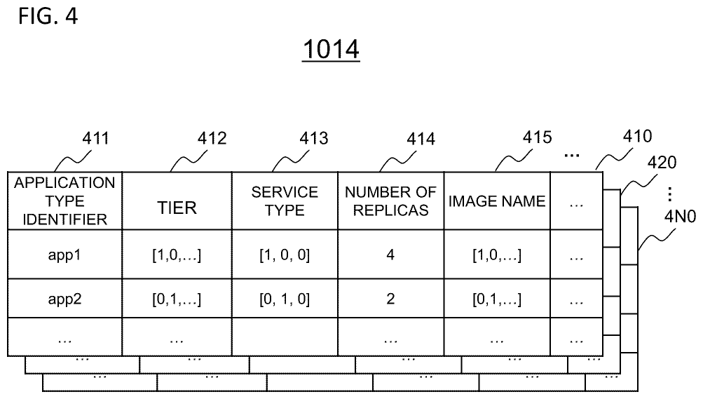

Next, a configuration of a past application metadata database according to the embodiment of the present disclosure is explained with reference to FIG. 4.

FIG. 4 is a figure depicting a configuration example of the metadata database 1014 according to the embodiment of the present disclosure. As mentioned above, the metadata database 1014 is a database that stores metadata tables having metadata related to applications executed by the node clusters 3010, 3020, . . . and 30N0 (e.g., past applications deployed on the node clusters in the past). In the metadata database 1014, there are dedicated metadata tables 410, 420, and 4N0 for the node clusters 3010, 3020, . . . , and 30N0, respectively. For example, there is the metadata table 410 corresponding to the node cluster 3010, there is the metadata table 420 corresponding to the node cluster 3020, and there is the metadata table 4N0 corresponding to the node cluster 30N0.

As an example, the metadata table 410 stores application metadata of past applications having been executed on the node cluster 3010.

As depicted in FIG. 4, the metadata table 410 may store application type identifiers 411 such as “app1” or “app2” for uniquely identifying the types of particular past applications, tiers 412 of the applications such as “frontend” or “backend,” service types 413 such as “ClusterIP” or “NodePort,” the numbers of replicas 414 representing the numbers of containers, and container image names 415 such as “Web Server A” or “Web Server B.”

Here, information such as the tiers 412, the service types 413, and the image names 415 in text formats are stored in vector formats obtained by one-hot encoding mentioned later. More specifically, regarding an application whose application type identifier is “app1” in the metadata table 410, the value “frontend” is expressed as “1, 0, . . . ” in a vector format, the value “NodePort” is expressed as “1, 0, 0” in a vector format, and the value “Web Server A” is expressed as “1, 0, . . . ”

In an initial stage, the respective metadata tables 410, 420, and 4N0 may store metadata of benchmark applications executed on the node clusters 3010, 3020, . . . , and 30N0.

Thereafter, when a new application (i.e., the estimation target application requested by the client terminal 4000) is to be executed on a particular node cluster, in a case where a past application similar to the new application (i.e., satisfying the predetermined degree-of-similarity criterion) has been executed on the same node cluster and its application metadata has already been stored in the metadata database 1014, metadata of the new application is not stored in the metadata database 1014 (i.e., in order to prevent recording of overlapping metadata). On the other hand, in a case where there are no past applications similar to the estimation target application (i.e., satisfying the predetermined degree-of-similarity criterion) that have been executed on the same node cluster, application metadata of the estimation target application is stored in the metadata database 1014, and the metadata database 1014 is updated. Degrees of similarity here may be determined by any of methods for calculating degrees of similarity mentioned above (the Euclidean distance, etc.).

Whereas the configuration of the metadata table 410 has been explained above for convenience of explanation, the same applies to the metadata table 420 and the metadata table 4N0.

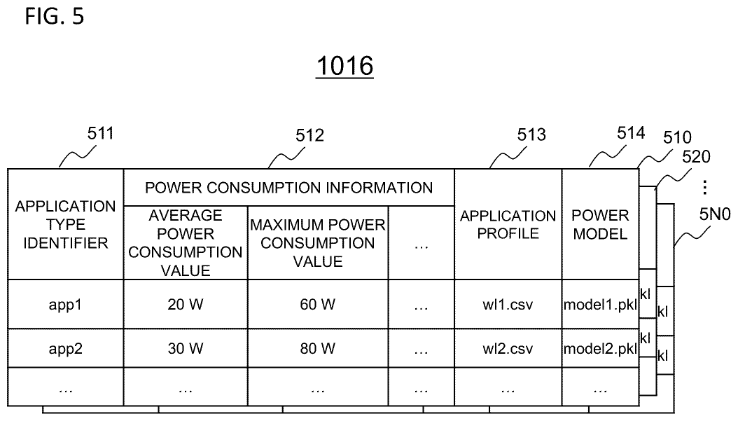

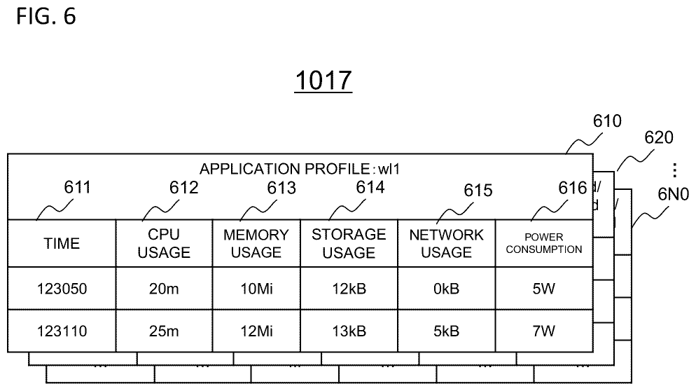

Next, the application power consumption database according to the embodiment of the present disclosure is explained with reference to FIG. 5 and FIG. 6.

FIG. 5 is a figure depicting a configuration example of the application power consumption database 1016 according to the embodiment of the present disclosure. As mentioned above, the application power consumption database 1016 is a database that stores power consumption information about applications executed by the node clusters 3010, 3020, . . . , and 30N0, information about the storage locations of application profiles representing the resource usage of the applications, and information about the storage locations of power models for estimating power consumption of the applications.

In the application power consumption database 1016, there are dedicated application power consumption tables 510, 520, and 5N0 for the node clusters 3010, 3020, and 30N0, respectively. For example, there is the application power consumption table 510 corresponding to the node cluster 3010, there is the application power consumption table 520 corresponding to the node cluster 3020, and there is the application power consumption table 5N0 corresponding to the node cluster 30N0.

The application power consumption table 510 stores power consumption information about past applications having been executed on the node cluster 3010, information about the storage locations of application profiles, and information about the storage locations of power models.

As depicted in FIG. 5, the application power consumption table 510 may store application type identifiers 511 such as “app1” or “app2” for uniquely identifying the types of particular past applications, power consumption information 512 representing the average power consumption values and maximum power consumption values of the particular applications, storage locations 513 of application profiles of the particular applications, and storage locations 514 of power models built on the basis of the application profiles of the particular applications.

As an example, as depicted in FIG. 5, regarding an application whose application type identifier is “app1” in the application power consumption table 510, “20 W” as the average power consumption value, “60 W” as the maximum power consumption value, “Wll.csv” as the storage location of the application profile, and “modell.pk” as the power model are stored.

In an initial stage, the application power consumption tables 510, 520, and 5N0 may store power consumption information about benchmark applications executed on the node clusters 3010, 3020, . . . , and 30N0.

Thereafter, when a new application (i.e., the estimation target application requested by the client terminal 4000) is executed on a particular node cluster, in a case where a past application (hereinafter, a similar application) similar to the estimation target application (i.e., satisfying the predetermined degree-of-similarity criterion) is to be executed on the same node cluster and the storage location of its power model has already been stored in the application power consumption database 1016, the execution managing section 1013 specifies, on the power model database 1018, a power model (e.g., a first power model) corresponding to the application profile (e.g., a first application profile) of the similar application.

Next, using the specified power model, the execution managing section 1013 generates a second power consumption estimation result representing a power consumption estimate of the estimation target. Next, the execution managing section 1013 collects a power consumption measurement value representing the actual power consumption in a case where the estimation target application is executed on a deployment destination node, and resource usage measurement values (measured values of resource usage such as processor usage, memory usage, storage usage, or network usage) representing the actual resource usage in a case where the estimation target application is executed on the deployment destination node. Next, in a case where the degree of difference between the power consumption measurement value and the second power consumption estimation result satisfies a predetermined degree-of-difference criterion, the execution managing section 1013 updates the application profile of the similar application on the basis of the collected resource usage measurement values, and updates the first power model on the basis of the updated first application profile and the power consumption measurement value.

Accordingly, in a case where power consumption estimated on the basis of the power model of a past application does not match the actual power consumption of the estimation target application in a case where the estimation target application is executed on a deployment destination node, the application profile and the power model of the past application are updated on the basis of information obtained by actual measurement, so that the precision of the power model can be enhanced.

A “degree of difference” here means the difference between an actually calculated value (e.g., a power consumption measurement value) and a value estimated by a power model (e.g., a second power consumption estimation result). In addition, the predetermined degree-of-difference criterion may be a threshold preset by an administrator or may be a threshold automatically set by statistical means.

Note that, while the first power consumption estimation result that is generated by the power consumption estimation method 300 mentioned above and that is used for determining a node to be the deployment destination of the estimation target application includes information such as the average power consumption value or maximum power consumption value of a similar application, the second power consumption estimation result generated on the basis of a power model is a prediction of power consumption taking into consideration the usage of resources to be used by the estimation target application, and accordingly, can represent an estimate finer than the first power consumption estimation result.

Meanwhile, in a case where a past application (hereinafter, a similar application) similar to the estimation target application has not been executed on the same node cluster, the execution managing section 1013 collects a power consumption measurement value representing the actual power consumption of the estimation target application in a case where the estimation target application is executed on the deployment destination node, and resource usage measurement values representing the actual resource usage of the estimation target application in a case where the estimation target application is executed on the deployment destination node, and creates, on the application profile database 1017, a new application profile (e.g., a second application profile) corresponding to the estimation target application on the basis of the resource usage measurement values. The second application profile of the estimation target application is created by measuring the processor usage, the memory usage, the storage usage, and the network usage in a case where the estimation target application is executed. The power consumption information about the estimation target application is obtained by subtracting the power consumption of other applications being executed on a node cluster other than the estimation target application from the actually measured power consumption of the node cluster, and is stored in an application power consumption table corresponding to the node cluster.

Next, on the basis of the created second application profile and the power consumption measurement value, the execution managing section 1013 builds a new power model (second power model) corresponding to the estimation target application, and stores the new power model in the application power consumption database 1016. More specifically, as the second power model corresponding to the estimation target application, the execution managing section 1013 may build a regression model that uses resource usage measurement values such as the processor usage, the memory usage, the storage usage, or the network usage as independent variables and that uses the power consumption measurement value as a dependent variable.

Accordingly, in a case where there are no past applications similar to the estimation target application, a new application profile and power model corresponding to the estimation target application can be created. By using the application profile and power model thus created, power consumption taking into consideration the resource usage of the estimation target application can be accurately estimated.

Whereas the configuration of the application power consumption table 510 has been explained above for convenience of explanation, the same applies to the application power consumption table 520 and the application power consumption table 5N0.

FIG. 6 is a figure depicting a configuration example of the application profile database 1017 according to the embodiment of the present disclosure. As mentioned above, the application profile database 1017 is a database that stores information about application profiles representing the resource usage of applications. In the application profile database 1017, there are dedicated application profiles 610, 620, and 6N0 for respective past applications. For example, these application profiles 610, 620, and 6N0 may be CSV (comma separated variable) files.

As depicted in FIG. 6, for example, regarding a particular application profile identifier such as “wll,” the application profile 610 may store times 611 at which measurement of particular resource usage was performed, CPU usage 612 (millicpu (m)) of the application, memory usage 613 (mebibytes (Mi)) of the application, storage usage 614 (kilobytes (kB)) of the application, network usage 615 (kilobytes (kB)) of the application, and power consumption 616 (watts (W)). In a case where the target application is singly executed on a node, the power consumption 616 may be measured as the overall power consumption value of the node, and, in a case where a plurality of applications are executed on the same node, the power consumption 616 may be a power consumption value estimated on the basis of a power model.

As an example, regarding a particular application, the application profile 610 represents that the CPU usage was “20 m,” the memory usage was “10 Mi,” the storage usage was “12 kB,” the network usage was “0 kB,” and the power consumption was “5 W” at a measurement time “123005.”

Whereas the configuration of the application profile 610 has been explained above for convenience of explanation, the same applies to the application profile 620 and the application profile 6N0.

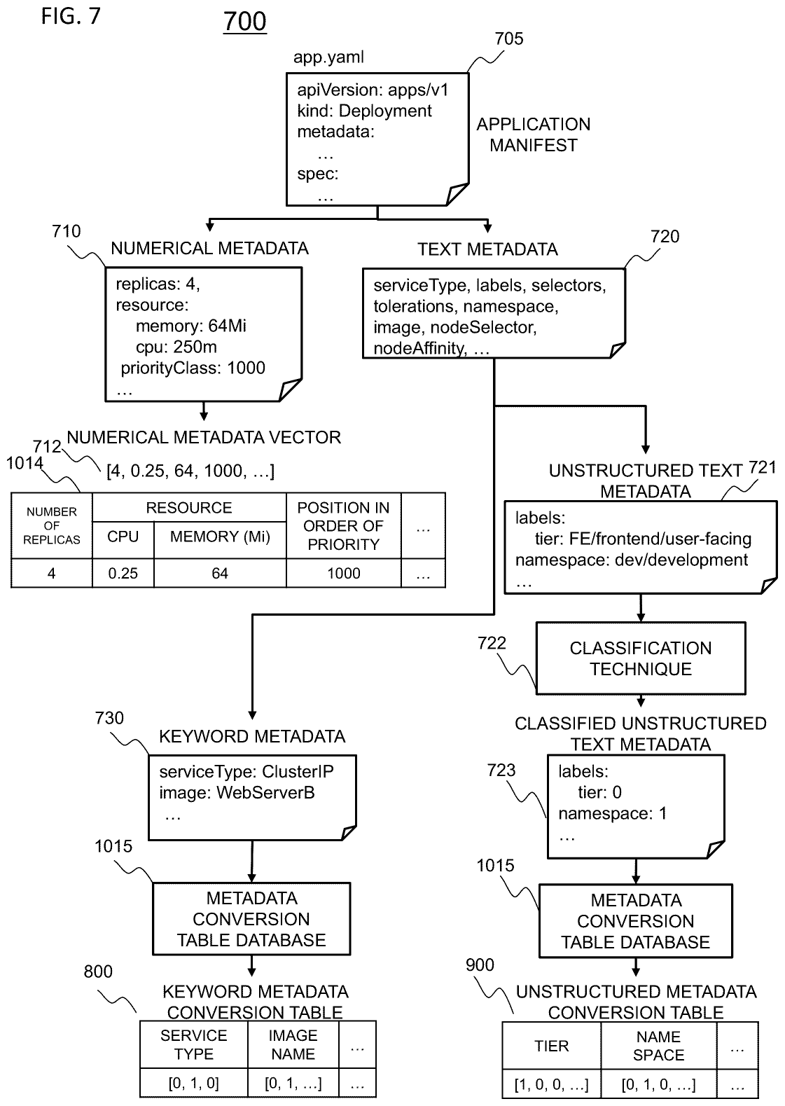

Next, an example of metadata conversion according to the embodiment of the present disclosure is explained with reference to FIG. 7.

FIG. 7 is a flowchart depicting an example of metadata conversion 700 according to the embodiment of the present disclosure. As mentioned above, application metadata may include text metadata that expresses application resources such as container image names or service type labels by text, in addition to numerical metadata that expresses application resources by numerical values. In this case, it is desirable if the metadata in text formats is converted into vector formats by the metadata conversion 700 according to the embodiment of the present disclosure, in order to more easily compare metadata of the estimation target application and metadata of the past applications.

FIG. 7 is a figure depicting a procedure of the metadata conversion 700 according to the embodiment of the present disclosure.

As mentioned above, for example, an application manifest 705 that the power consumption estimating section 1011 receives from the client terminal 4000 may be a YAML file designating the specifications of application resources. As mentioned above, the specifications of the application resources are application metadata of the application. In addition, the application metadata may include two types of metadata, which are numerical metadata 710 including numerical values and text metadata 720 including text.

The numerical metadata 710 is metadata representing the specifications of application resources by numerical values. For example, as depicted in FIG. 7, the numerical metadata 710 may represent that the number of replicas of the application is “4,” the processor usage of the application is “0.25%,” the memory usage of the application is “64 Mi,” and the position of the application in the order of priority is “1000.” Since the numerical metadata 710 is expressed by numerical values already, the numerical metadata 710 can be expressed as a numerical metadata vector 712 (4, 0.25, 64, 1000) including those numerical values and stored in the metadata database 1014.

The text metadata 720 is metadata representing the specifications of application resources by text. In addition, the text metadata 720 may include two types of metadata, which are keyword metadata 730 representing the specifications of application resources by using predetermined fixed text values (i.e., keywords), and unstructured text metadata 721 representing the specifications of application resources by using text that can be input freely.

The keyword metadata 730 can be converted into vector formats through one-hot encoding with reference to a keyword metadata conversion table 800 in the metadata conversion table database 1015. Each vector obtained by performing one-hot encoding is a vector in which all elements except for one element are set to “zero.” The element which is not set to “zero” is set to “1.” The position of the value “1” in the vector is unique to a text value, and the size of the vector is equal to the number of unique text values. As an example, the service type “ClusterIP” in the keyword metadata 730 depicted in FIG. 7 is expressed as “0, 1, 0” in a vector format, and the image “Web Server B” is expressed as “0, 1, . . . ” in a vector format.

Meanwhile, since text data in the unstructured text metadata 721 is text information that is input freely by a user, for example, one thing with a single meaning may be written or called in different ways inconsistently. For example, all of the values “FE,” “frontend,” and “user-facing” are written in different ways but are information meaning that the application is for frontend services. Similarly, all of the values “dev” and “development” are information meaning that the application is being developed. 1. In view of this, it is desirable if a classification technique 722 using a trained neural network is used in order to convert such unstructured text metadata with inconsistency into vector formats with consistency. By processing the unstructured text metadata 721 by the classification technique 722, classified unstructured text metadata 723 in which pieces of text information meaning the same concept are all classified into the same category can be obtained.

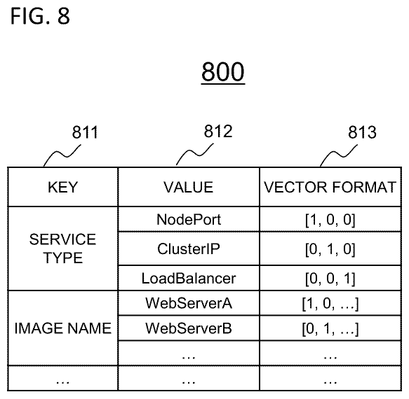

Thereafter, the classified unstructured text metadata 723 thus obtained can be converted into vector formats through one-hot encoding with reference to an unstructured text metadata conversion table 900 in the metadata conversion table database 1015. As an example, in the classified unstructured text metadata 723 depicted in FIG. 8, the value of a tier is expressed as “1, 0, 0, . . . ” in a vector format, and the value of a name space is expressed as “0, 1, 0, . . . ” in a vector format.

According to the metadata conversion 700 explained above, application metadata can be converted into vector formats and stored in the metadata database 1014 mentioned above. In addition, since entire metadata can thus be expressed in vector formats, it becomes possible to compare metadata of the estimation target application and metadata of the past applications by using their metadata vectors, and the degrees of similarity between the estimation target application and the past applications can be calculated easily.

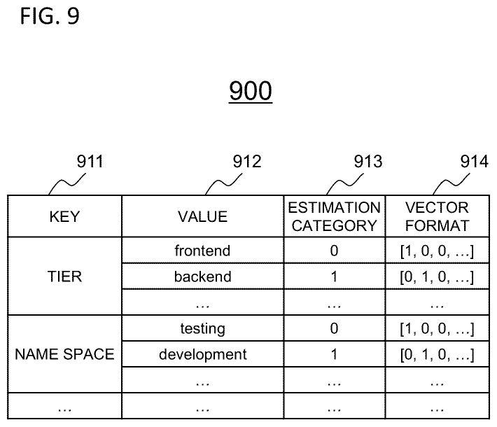

In the metadata conversion 700 mentioned above, the metadata conversion tables stored in the metadata conversion table database are used in order to convert metadata in text formats into vector formats. Accordingly, next, the metadata conversion table database according to the embodiment of the present disclosure is explained with reference to FIG. 8 and FIG. 9.

FIG. 8 is a figure depicting an example of the keyword metadata conversion table 800 in the metadata conversion table database 1015 according to the embodiment of the present disclosure. The keyword metadata conversion table 800 is a table that is used for converting keyword metadata into vector formats by associating particular keywords in text metadata with predetermined vectors.

As depicted in FIG. 8, the keyword metadata conversion table 800 stores information about keys 811 such as “service type” or “image name” representing the names of application resources, possible values 812 of the application resources such as “Nodeport” or “Web Server A,” and vector formats 813 corresponding to the values 812.

By using the keyword metadata conversion table 800, particular keywords in application metadata can be converted into vector formats. As an example, in a case where the value of an application resource as “service type” is “Nodeport,” the value “Nodeport” can be converted into a vector format, [1, 0, 0], by using the keyword metadata conversion table 800.

FIG. 9 is a figure depicting an example of the unstructured text metadata conversion table 900 in the metadata conversion table database 1015 according to the embodiment of the present disclosure. For example, the unstructured text metadata conversion table 900 is a table that is used for converting unstructured text metadata into vector formats by associating unstructured text information freely input by a user with predetermined vectors.

As depicted in FIG. 9, the unstructured text metadata conversion table 900 stores information about keys 911 such as “tier” or “name space” representing the names of application resources, possible values 912 of the application resources such as “frontend” or “development,” estimation categories 913 into which the values 912 are classified by the neural-network-based classification technique mentioned above, and vector formats 914 corresponding to the values 912.

By using the unstructured text metadata conversion table 900, unstructured text metadata in application metadata can be converted into vector formats. As an example, in a case where the value of an application resource as “tier” is “backend,” the value “backend” can be converted into a vector format, [0, 1, 0, . . . ], by using the unstructured text metadata conversion table 900.

Note that it is assumed here that, before conversion into vector formats, the unstructured text metadata in the application metadata has already been classified into particular categories by the neural-network-based classification technique.

In an initial stage, the keyword metadata conversion table 800 and the unstructured text metadata conversion table 900 in the metadata conversion table database 1015 mentioned above are configured on the basis of application metadata related to benchmark applications.

Thereafter, when a new application (e.g., a requested application) is executed on a particular node cluster, the keyword metadata conversion table 800 and the unstructured text metadata conversion table 900 are updated on the basis of application metadata extracted from an application manifest of the new application.

The power consumption estimation means explained above makes it possible to accurately estimate the power consumption of diverse applications by calculating the degree of similarity between a target application to be deployed on a node in a distributed computing environment and each of applications executed in the past on the node, on the basis of metadata of the respective applications, and using information about power consumption measured about a past application satisfying a predetermined degree-of-similarity criterion.

On the basis of the power consumption estimate of the application thus generated, the application can be deployed on an appropriate node cluster. In addition, by measuring and analyzing the actual power consumption of the application after the application is deployed on the appropriate node cluster, the precision of a power model for estimating power consumption taking into consideration the resource usage of the application can be evaluated. In a case where, as a result of the evaluation, the precision of the power model does not satisfy a predetermined criterion (i.e., in a case where an estimate generated by the power model differs from an actually measured value), the power model is updated on the basis of information about the actual power consumption of the application, so that the precision of the power model can be enhanced.

Meanwhile, in a case where there are no past applications having a calculated degree of similarity to the estimation target application which degree satisfies the predetermined degree-of-similarity criterion, a power consumption estimate of the estimation target application is generated on the basis of the average power consumption value of the past applications executed on the node cluster. Thereafter, the estimation target application is deployed on an appropriate node cluster on the basis of the power consumption estimate. In addition, by measuring and analyzing the actual power consumption of the deployed application, a new power model corresponding to the application can be built.

By causing node clusters to host various applications, and updating an existing power model of each hosted application, creating a new power model, and so on over time in this manner, a repertoire of power models corresponding to diverse applications is built, and accordingly, it becomes possible to accurately estimate the power consumption of the diverse applications.

Whereas an embodiment of the present invention has been explained above, the present invention is not limited to the embodiment mentioned above and can be changed in various manners within the scope not departing from the gist of the present invention.

### DESCRIPTION OF REFERENCE SYMBOLS

160: Power consumption estimation system
1000: Cluster managing device
1010: Power consumption estimating device
1011: Power consumption estimating section
1013: Execution managing section
1014: Metadata database
1015: Metadata conversion table database
1016: Application power consumption database
1017: Application profile database
1018: Power model database
1020: Input/output device
1030: Processor
1040: Memory
1050: Network interface
2000: Communication network
3010, 3020, . . . , 30N0: Node cluster
3011: Master node
3012, 3013, 301N: Slave node
4000: Client terminal

1. A power consumption estimating device that estimates power consumption of an estimation target application to be deployed on a node cluster including a plurality of nodes, the power consumption estimating device comprising:
a metadata database that stores past application metadata related to each of past applications executed in a past on the node cluster;
a power consumption database including power consumption information representing power consumption of the past applications; and
a power consumption estimating section that estimates the power consumption of the estimation target application, wherein
the power consumption estimating section
acquires an application manifest including information about the estimation target application,
extracts, from the application manifest, target application metadata which is metadata related to the estimation target application,
calculates a degree of similarity of the target application metadata to the past application metadata stored on the metadata database,
in a case where there is a similar application having a calculated degree of similarity which satisfies a predetermined degree-of-similarity criterion in the past applications, extracts, from the power consumption database, first power consumption information corresponding to the similar application, and
outputs the first power consumption information as a first power consumption estimation result representing a power consumption estimate of the estimation target application.

2. The power consumption estimating device according to claim 1, wherein, in a case where there are no similar applications having a calculated degree of similarity to the target application metadata which degree satisfies the predetermined degree-of-similarity criterion in the past applications, the power consumption estimating section outputs, as the first power consumption estimation result, an average power consumption value of the past applications stored in the power consumption database.

3. The power consumption estimating device according to claim 1, further comprising:
an application profile database that stores application profiles representing information about usage of resources that are used during execution of the past applications; and
a power model database that stores power models that are built on a basis of the application profiles and that estimate power consumption of execution of the past applications.

4. The power consumption estimating device according to claim 3, further comprising:
an execution managing section that determines a deployment destination node to be a deployment destination of the estimation target application from the node cluster on a basis of the first power consumption estimation result, and that deploys the estimation target application on the deployment destination node.

5. The power consumption estimating device according to claim 4, wherein,
after deploying the estimation target application on the deployment destination node,
in a case where there is a similar application having a calculated degree of similarity to the target application metadata which degree satisfies the predetermined degree-of-similarity criterion in the past applications,
the execution managing section
specifies a first power model corresponding to a first application profile of the similar application in the power model database,
generates a second power consumption estimation result representing a power consumption estimate of the estimation target application, by using the specified first power model,
collects a power consumption measurement value representing actual power consumption in a case where the estimation target application is executed on the deployment destination node, and a resource usage measurement value representing actual resource usage in a case where the estimation target application is executed on the deployment destination node, and,
in a case where a degree of difference between the power consumption measurement value and the second power consumption estimation result satisfies a predetermined degree-of-difference criterion, updates, on a basis of the resource usage measurement value, the first application profile of the similar application, and updates the first power model on a basis of the updated first application profile and the power consumption measurement value.

6. The power consumption estimating device according to claim 4, wherein,
after deploying the estimation target application on the deployment destination node,
in a case where there are no similar applications having a calculated degree of similarity to the target application metadata which degree satisfies the predetermined degree-of-similarity criterion in the past applications,
the execution managing section
collects a power consumption measurement value representing actual power consumption in a case where the estimation target application is executed on the deployment destination node, and a resource usage measurement value representing actual resource usage in a case where the estimation target application is executed on the deployment destination node,
creates, on the application profile database, a second application profile corresponding to the estimation target application on a basis of the resource usage measurement value, and
builds, as a second power model corresponding to the estimation target application, a regression model that uses the resource usage measurement value as an independent variable and that uses the power consumption measurement value as a dependent variable, on a basis of the created second application profile and the power consumption measurement value, and stores the regression model in the power model database.

7. The power consumption estimating device according to claim 1, wherein
the target application metadata includes text metadata including text and numerical metadata including numerical values,
the text metadata includes keyword metadata including predetermined fixed text values and unstructured text metadata including text values that can be input freely, and
the power consumption estimating device further includes a metadata conversion table database that stores a keyword metadata conversion table for converting the keyword metadata into a vector format and an unstructured text metadata conversion table for converting the unstructured text metadata into a vector format.

8. The power consumption estimating device according to claim 7, wherein
the power consumption estimating section
converts the numerical metadata into a first metadata vector,
converts the keyword metadata into a second metadata vector by using the keyword metadata conversion table,
classifies the unstructured text metadata into a predetermined metadata category by using classification means that uses a trained neural network,
converts the unstructured text metadata into a third vector by using the metadata category and the unstructured text metadata conversion table, and
calculates, as a Euclidean distance, the degree of similarity of the target application metadata to the past application metadata stored in the metadata database, by comparing each of the first metadata vector, the second metadata vector, and the third metadata vector with the metadata database that stores the past application metadata in a vector format.

9. The power consumption estimating device according to claim 8, wherein the power consumption estimating section adjusts an influence of any of the first metadata vector, the second metadata vector, and the third metadata vector on the degree of similarity by weighting the metadata vector.

10. A power consumption estimation system in which a node cluster including a plurality of nodes, a cluster managing device that manages the node cluster, and a client terminal that requests the node cluster to execute an application are connected via a communication network, wherein
the cluster managing device includes a power consumption estimating device including
a metadata database that stores past application metadata related to each of past applications executed on the node cluster,
a power consumption database including power consumption information representing power consumption of the past applications,
a power consumption estimating section that estimates power consumption of an estimation target application, and
an execution managing section that manages an application to be deployed on the node cluster,
the power consumption estimating section
acquires an application manifest including information about the estimation target application from the client terminal,
extracts target application metadata which is metadata related to the estimation target application from the application manifest,
calculates a degree of similarity of the target application metadata to the past application metadata stored in the metadata database,
in a case where there is a similar application having a calculated degree of similarity which satisfies a predetermined degree-of-similarity criterion in the past applications, extracts, from the power consumption database, first power consumption information corresponding to the similar application, and
generates the first power consumption information as a first power consumption estimation result representing a power consumption estimate of the estimation target application, and
the execution managing section
determines a deployment destination node to be a deployment destination of the estimation target application from the node cluster on a basis of the first power consumption estimation result, and
deploys the estimation target application on the deployment destination node.

11. A power consumption estimation method for estimating power consumption of an estimation target application to be deployed on a node cluster including a plurality of nodes, the power consumption estimation method comprising:
a step of acquiring an application manifest including information about the estimation target application;
a step of extracting, from the application manifest, target application metadata which is metadata related to the estimation target application;
a step of converting the target application metadata into a metadata vector in a vector format by using one-hot encoding means;
a step of calculating a degree of similarity of the metadata vector to past application metadata related to each of past applications executed on the node cluster;
a step of, in a case where there is a similar application having a calculated degree of similarity which satisfies a predetermined degree-of-similarity criterion in the past applications, specifying first power consumption information corresponding to the similar application;
a step of generating the first power consumption information as a first power consumption estimation result representing a power consumption estimate of the estimation target application;
a step of determining a deployment destination node to be a deployment destination of the estimation target application from the node cluster on a basis of the first power consumption estimation result; and
a step of deploying the estimation target application on the deployment destination node.
